(19) United States
(12) Patent Application Publication
(10) Pub. No.: US 2026/0123385 A1
(43) Pub. Date: Apr. 30, 2026

(54) SEMICONDUCTOR STRUCTURE WITH BACKSIDE BUTTED CONTACTS

(71) Applicant: Taiwan Semiconductor Manufacturing Company, Ltd., Hsin-Chu (TW)

(72) Inventors: Yung-Ting Chang, New Taipei City (TW); Jui-Lin Chen, Taipei City (TW); Chen-Ming Lee, Yangmei City (TW); Feng-Ming Chang, Zhubei City (TW)

(21) Appl. No.: 19/195,975

(22) Filed: May 1, 2025

Related U.S. Application Data
(60) Provisional application No. 63/714,574, filed on Oct. 31, 2024.

(51) Int. Cl. H01L 23/522; H01L 23/528; H10B 10/00; H10D 30/00; H10D 30/43; H10D 62/10; H10D 62/13; H10D 64/23; H10D 64/27

(52) U.S. Cl. CPC H10W 20/42; H10B 10/12; H10D 30/43; H10D 30/502; H10D 62/121; H10D 62/151; H10D 64/256; H10D 64/518; H10W 20/435; H10W 20/498

(57) ABSTRACT

A semiconductor structure includes an active region including a semiconductor fin base, a stack of nanostructures over the semiconductor fin base, and an epitaxial feature over the semiconductor fin base and connected to at least one of the nanostructures, the active region extending lengthwise in a first direction. The semiconductor structure further includes a gate structure wrapping around each of the nanostructures, the gate structure extending lengthwise in a second direction perpendicular to the first direction, and a backside butted contact disposed directly under and electrically connected to the epitaxial feature and the gate structure. A portion of the backside butted contact extends into the gate structure and the epitaxial feature.

### PRIORITY DATA

This is a non-provisional application of and claims the benefit of U.S. Provisional Application No. 63/714,574 filed Oct. 31, 2024, the entirety of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. Although existing structures and methods have been generally adequate for their intended purposes, they are not entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a circuit schematic of an SRAM cell according to various aspects of the present disclosure.

FIG. 2 illustrates a top view of an SRAM cell, according to various aspects of the present disclosure.

FIG. 3 illustrates a fragmentary top view of a frontside interconnect layer of an SRAM quad-cell, according to various aspects of the present disclosure.

FIGS. 4 and 5 illustrates fragmentary top views of a backside interconnect layer of an SRAM quad-cell, according to various aspects of the present disclosure.

FIG. 6 illustrates a fragmentary top view of a frontside interconnect layer of an SRAM quad-cell and a frontside interconnect structure thereover, according to various aspects of the present disclosure.

FIG. 7 illustrates a fragmentary top view of a backside interconnect layer of an SRAM quad-cell and a backside interconnect structure therebelow, according to various aspects of the present disclosure.

FIG. 8 illustrates a fragmentary cross-sectional view along cross section A-A in FIGS. 3-4 and 6-7, according to various aspects of the present disclosure.

FIGS. 9, 10, 11, and 12 illustrates fragmentary cross-sectional views along cross section B-B in FIGS. 3-4 and 6-7, according to various aspects of the present disclosure.

FIG. 13 illustrates a fragmentary cross-sectional view along cross section C-C in FIGS. 3-4 and 6-7, according to various aspects of the present disclosure.

FIG. 14 illustrates a fragmentary cross-sectional view along cross section D-D in FIGS. 3-4 and 6-7, according to various aspects of the present disclosure.

FIG. 15 illustrates a fragmentary top view of a backside interconnect layer of an SRAM quad-cell and a backside interconnect structure therebelow, according to various aspects of the present disclosure.

FIGS. 16 and 17 illustrate fragmentary cross-sectional views along cross section D-D in FIG. 15, according to various aspects of the present disclosure.

FIG. 18 illustrates a fragmentary top view of a frontside interconnect layer of an SRAM quad-cell, according to various aspects of the present disclosure.

FIG. 19 illustrates a fragmentary top view of a frontside interconnect layer of an SRAM quad-cell and a frontside interconnect structure thereover, according to various aspects of the present disclosure.

FIG. 20 illustrates a fragmentary top view of a backside interconnect layer of an SRAM quad-cell and a backside interconnect structure therebelow, according to various aspects of the present disclosure.

FIG. 21 illustrates a fragmentary cross-sectional view along cross section B-B in FIGS. 18-20, according to various aspects of the present disclosure.

FIG. 22 illustrates a fragmentary top view of a frontside interconnect layer of an SRAM quad-cell, according to various aspects of the present disclosure.

FIG. 23 illustrates a fragmentary top view of a frontside interconnect layer of an SRAM quad-cell and a frontside interconnect structure thereover, according to various aspects of the present disclosure.

FIG. 24 illustrates a fragmentary top view of a backside interconnect layer of an SRAM quad-cell and a backside interconnect structure therebelow, according to various aspects of the present disclosure.

FIG. 25 illustrates a fragmentary cross-sectional view along cross section C-C in FIGS. 22-24, according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Static random-access memory (SRAM) is an electronic data storage device implemented on a semiconductor-based integrated circuit and generally has much faster access times than other types of data storage technologies. SRAM is popular in high-speed communication, image processing and system-on-chip (SOC) applications. A bit can be read from or written into an SRAM cell within a few nanoseconds. An SRAM cell include transistors with metal interconnect structures above the transistors. The metal interconnect structures include metal lines for interconnecting transistor gates and source/drain regions, such as signal lines for routing bit line and word line signals to the cell components, as well as power rails (such as metal lines for power voltage and electrical ground) for providing power to the cell components. Contacts and respective contact vias electrically connect the cell components to the signal lines and the power rails.

Conventionally, SRAM devices are built in a stacked-up fashion, having transistors at the lowest level and interconnect structures (contacts, vias, and metal lines) on top of the transistors to provide connectivity to the transistors. For example, interconnect structures may include a frontside butted contact that electrically connects the source/drain feature to a gate of the pull-down transistor and the pull-up transistor, which takes up space above the transistors. Power rails are also above the transistors and may be part of the interconnect structures. With the increasing downscaling of SRAM devices, so do the power rails. As available layout area becomes limited, metal lines in the power rails are generally formed to have reduced dimensions. This inevitably leads to increased voltage drop across the power rails, as well as increased power consumption, which has become a key issue in further boosting performance of SRAM devices. Therefore, although existing approaches in semiconductor fabrication have been generally adequate for their intended purposes, they have not been entirely satisfactory in all respects in the context of SRAM devices.

The present disclosure is generally related to structures having backside butted contacts (also referred to as backside slot vias). In some embodiments, the structure includes an SRAM device. The backside butted contact is disposed below and electrically connects a source/drain feature to a gate of a pull-down transistor and a pull-up transistor of an SRAM cell to provide cross-latching. This provides space savings in a frontside interconnect layer of the SRAM cell, thus providing more flexibility to design of frontside metal lines (e.g., M0 metal lines) in a frontside interconnect structure over the SRAM cell. M0 metal line for a positive supply voltage Vdd may be wider to reduce resistance and to enhance maximum operating voltage (Vmax). In some embodiments, sources of pull-down transistors are coupled to a backside rail by backside source/drain contacts or a backside bar contact to reduce resistance in connecting to a voltage Vss, which may be an electrical ground or a negative supply voltage in some embodiments.

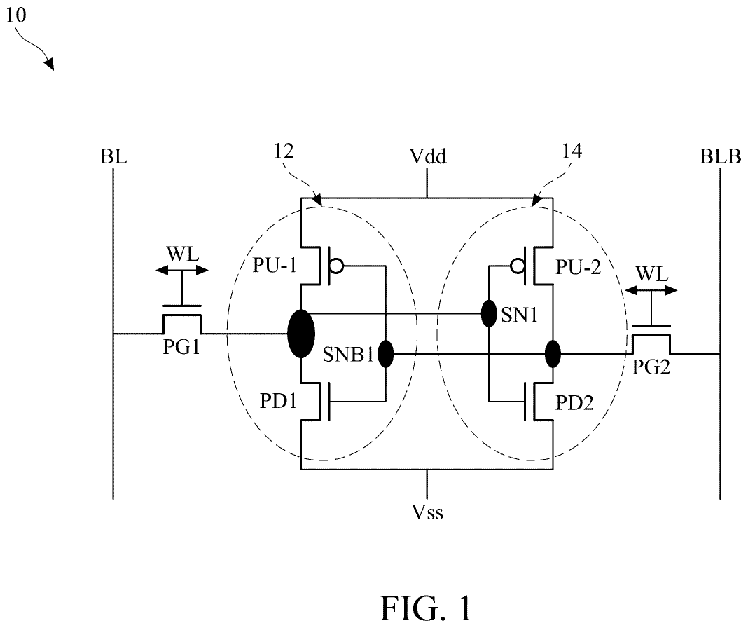

FIG. 1 illustrates an example type of memory device in which transistors such as planar transistors, FinFET transistors, or gate-all-around (GAA) transistors may be implemented. In that regard, FIG. 1 illustrates the circuit schematic of an example SRAM device, for example, as a single-port SRAM cell (e.g., 1-bit SRAM cell) 10. The single-port SRAM cell 10 includes first and second pass-gate transistors PG1 and PG2, first and second pull-up transistors PU1 and PU2, and first and second pull-down transistors PD1 and PD-2. The gates of the first and second pass-gate transistors PG1 and PG2 are electrically coupled to word-line (WL) that determines whether the SRAM cell 10 is selected or not. In the SRAM cell 10, a memory bit (e.g., a latch or a flip-flop) is formed of the first and second pull-up transistors PU1 and PU2 and the first and second pull-down transistors PD1 and PD2 to store a bit of data. The complementary values of the bit are stored in a first storage node SN1 and a first complementary storage node SNB1. The stored bit can be written into, or read from, the SRAM cell 10 through Bit-line (BL) and Bit-Line Bar (BLB). In this arrangement, the BL and BLB may carry complementary bit-line signals. The SRAM cell 10 is powered through a positive power supply voltage Vdd and is also connected to a ground potential Vss.

The SRAM cell 10 includes a first inverter 12 formed of the first pull-up transistor PU1 and the first pull-down transistor PD1 as well as a second inverter 14 formed of the second pull-up transistor PU2 and the second pull-down transistor PD2. As shown in FIG. 1, drains of the first pull-up transistor PU1 and the first pull-down transistor PD1 are coupled together and drains of the second pull-up transistor PU2 and the second pull-down transistor PD2 are coupled together. The first inverter 12 and the second inverter 14 are coupled between the positive supply voltage Vdd and the ground potential Vss. As shown in FIG. 1, the first inverter 12 and the second inverter 14 are cross-coupled. That is, the first inverter 12 has an input coupled to the output of the second inverter 14. Likewise, the second inverter 14 has an input coupled to the output of the first inverter 12. The output of the first inverter 12 is referred to as the first storage node SN1. Likewise, the output of the second inverter 14 is referred to as the first complementary storage node SNB1. In a normal operating mode, the first storage node SN1 is in the opposite logic state (logic high or logic low) as the first complementary storage node SNB1. By employing the two cross-coupled inverters, the SRAM cell 10 can hold the data using a latched structure so that the stored data will not be lost without applying a refresh cycle as long as power is supplied through Vdd.

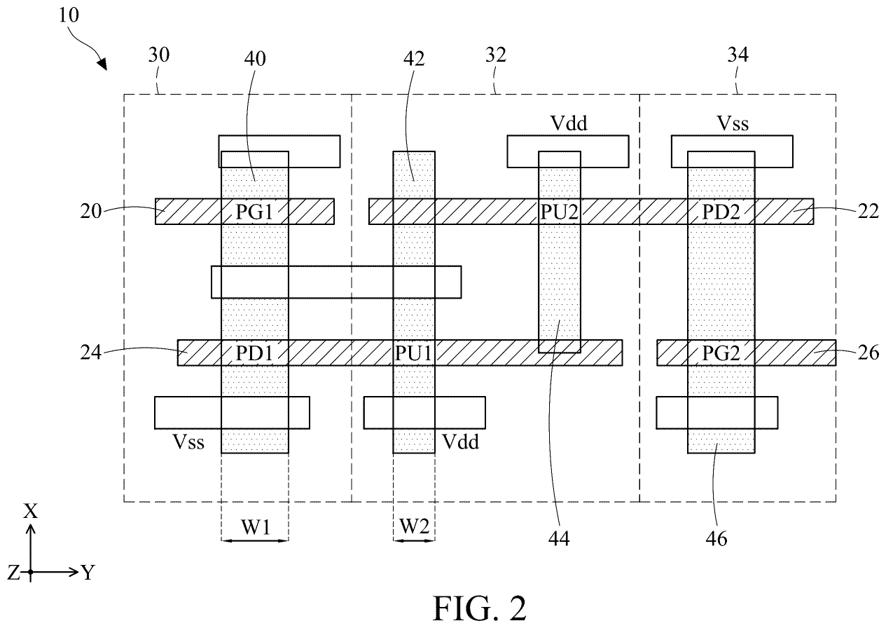

Referring to FIG. 2, shown therein is an example layout of the SRAM cell 10 in FIG. 1. Like the SRAM cell 10 in FIG. 1, the layout in FIG. 2 includes six (6) transistors functioning as the first pass-gate transistor PG1, the second pass-gate transistor PG2, the first pull-up transistor PU1, the second pull-up transistor PU2, the first pull-down transistor PD1, and the second pull down transistor PD2. In some implementations represented in FIG. 2, the SRAM cell 10 may be formed over an n-type well 32 (or N well 32) sandwiched between two p-type wells 30 and 34 (or P wells 30 and 34). The N well 32 and P wells 30, 34 are formed over a substrate. In some embodiments, as shown in FIG. 2, the first pass-gate transistor PG1, the first pull-down transistor PD1, the second pull-down transistor PD2, and the second pass-gate transistor PG2 may be formed over the P wells 30 and 34; and the first pull-up transistor PU1 and the second pull-up transistor PU2 are formed in the N well 32. In these embodiments, the first pass-gate transistor PG1, the first pull-down transistor PD1, the second pull-down transistor PD2, and the second pass-gate transistor PG2 are n-type GAA transistors; and the first pull-up transistor PU1 and the second pull-up transistor PU2 are p-type GAA transistors.

In some embodiments, the SRAM cell 10 includes four fin-shaped vertical stacks—a first fin-shaped vertical stack 40, a second fin-shaped vertical stack 42, a third fin-shaped vertical stack 44, and a fourth fin-shaped vertical stack 46. The first fin-shaped vertical stack 40 is formed over the P well 30 and forms the channel regions of the first pass-gate transistor PG1 and the first pull-down transistor PD1. The second fin-shaped vertical stack 42 and third fin-shaped vertical stack 44 are formed over the N well 32 and form the channel regions of the first pull-up transistor PU1 and the second pull-up transistor PU2, respectively. The fourth fin-shaped vertical stack 46 is formed over the P well 34 and forms the channel regions of the second pull-down transistor PD2 and the second pass-gate transistor PG2. Each of the first, second, third, and fourth fin-shaped vertical stacks 40, 42, 44, and 46 may include about two (2) to about ten (10) channel members. In some embodiments, each of the first, second, third, and fourth fin-shaped vertical stacks 40, 42, 44, and 46 includes 3 channel members. Each of the first, second, third, and fourth fin-shaped vertical stacks 40, 42, 44, and 46 may be referred to as an active region.

In some instances, the fin-shaped vertical stacks may be formed by depositing or epitaxially growing alternating layers of two different semiconductor materials, patterning the alternating layers to form fin-shaped structures, and selectively removing layers formed of one of the two semiconductor materials. For example, alternating layers of epitaxially grown silicon (Si) and silicon germanium (SiGe) can be formed on a substrate. The substrate may be a silicon (Si) substrate. The alternating layers may then be patterned to form fin-shaped structures that include stacks of interleaved Si strips and SiGe stripes. In processes to form a channel region of a transistor in a SRAM cell, the channel region of the fin-shaped structures may undergo different etching processes to selectively remove the SiGe strips, releasing silicon layers as suspended silicon channel members. The channel members may assume different shapes and dimensions and may be referred to as nanostructure, nanowires, or nanosheets. These fin-shaped structures are separated by an isolation feature, such as a shallow trench isolation (STI) feature. In some implementations, each of the fin-shaped vertical stacks may include a top portion formed from the alternating layers and a base portion formed from the substrate. The base portions of the fin-shaped vertical stacks have a shape of a fin and may be referred to as fin structures. The base portions of the fin-shaped vertical stacks may be substantially buried in the isolation feature and top ends of the base portions of the fin-shaped vertical stacks may be level with a top surface of the isolation feature. The top portions of the fin-shaped vertical stacks extend from and rise above the isolation feature.

Reference is still made to FIG. 2. The channel members in the first fin-shaped vertical stack 40 form channel regions of the first pass-gate transistor PG1 and the first pull-down transistor PD1. The channel members in the second fin-shaped vertical stack 42 form channel regions of the first pull-up transistor PU1. The channel members in the third fin-shaped vertical stack 44 form channel regions of the second pull-up transistor PU2. The channel members in the fourth fin-shaped vertical stack 46 form channel regions of the second pull-down transistor PD2 and the second pass-gate transistor PG2. In the depicted embodiments, the first fin-shaped vertical stack 40 and the fourth fin-shaped vertical stack 46 are used to form n-type GAA transistors and the second fin-shaped vertical stack 42 and the third fin-shaped vertical stack 44 are used to form p-type GAA transistors. The first fin-shaped vertical stack 40 and the fourth fin-shaped vertical stack 46 may be referred to as n-type active regions. The second fin-shaped vertical stack 42 and the third fin-shaped vertical stack 44 may be referred to as p-type active regions. In the embodiments illustrated in FIG. 2, the first pass-gate transistor PG1, the first pull-down transistor PD1, the second pass-gate transistor PG2, the second pull-down transistor PD2 are n-type GAA transistors, and the first pull-up transistor PU1 and the second pull-up transistor PU-2) are p-type GAA transistors. In FIG. 2, each of the first fin-shaped vertical stack 40 and fourth fin-shaped vertical stack 46 has a first width W1 along the Y direction and each of the second fin-shaped vertical stack 42 and the third fin-shaped vertical stack 44 has a second width W2 along the Y direction. In some embodiments, in order to achieve better read/write performance, the n-type GAA transistors have greater channel widths than the p-type GAA transistors. That is, the first width W1 may be greater than the second width W2. In some instances, a ratio of the first width W1 to the second width W2 (W1/W2) is between about 1 and about 5, including between about 1.1 and about 3.0.

As illustrated in FIG. 2, a channel of the first pass-gate transistor PG1 is controlled by a gate structure 20, channels of the first pull-down transistor PD1 and the first pull-up transistor PU1 are controlled by a gate structure 24, channels of the second pull-down transistor PD2 and the second pull-up transistor PU2 are controlled by a gate structure 22, and a channel of the second pass-gate transistor PG2 is controlled by a gate structure 26. As the gate structures 20 and 22 are segmented from a single gate structure, they are aligned lengthwise along the Y direction. As the gate structures 24 and 26 are segmented from a single gate structure, they are aligned lengthwise along the Y direction. The first fin-shaped vertical stack 40, the second fin-shaped vertical stack 42, the third fin-shaped vertical stack 44, and the fourth fin-shaped vertical stack 46 extend lengthwise along the X direction, perpendicular to the Y direction. In circuit and physical design, the SRAM cell 10 shown in FIG. 2 may serve as a repeating unit in an SRAM array. For case of signal routing, adjacent SRAM cells 10 in an SRAM array may be mirror images of one another along their borders.

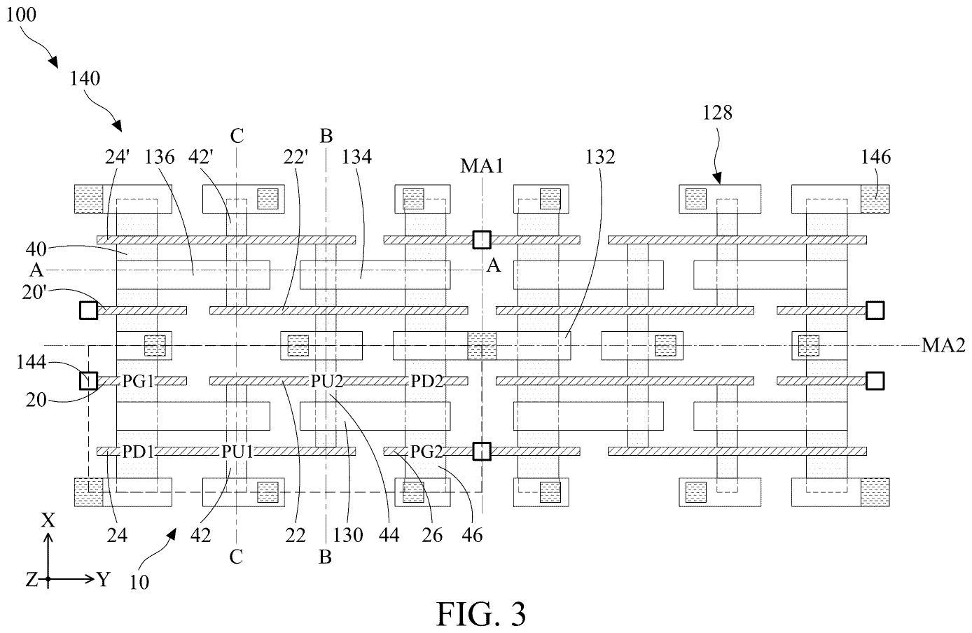

FIGS. 3-14 illustrate various aspects of some example embodiments where the structure includes backside butted contacts and backside source/drain contacts.

FIG. 3 illustrates a frontside interconnect layer 140 of a quad-cell 100 that includes 4 SRAM cells 10. An SRAM cell 10 is shown in FIG. 3 as a dotted rectangular box. For illustration purposes, FIG. 3 also includes a first mirror axis MA1, which extends along the X direction and a second mirror axis MA2, which extends along the Y direction. It can be seen that the SRAM cell across the first mirror axis MA1 from the SRAM cell 10 is a mirror image of the SRAM cell 10. Similarly, the SRAM cell across the second mirror axis MA2 from the SRAM cell 10 is a mirror image of the SRAM cell 10. The mirror imaging configuration allows merging of the pull-up transistors, the pull-down transistors, and pass-gate transistors for efficient routing and electrical connection. In some embodiments, the frontside interconnect layer 140 includes source/drain contacts 128 disposed over and connected to source/drains. As used herein, source/drain, source/drain region, source/drain feature, epitaxial source/drain, epitaxial source/drain feature, etc. may refer to a source of a device, a drain of a device, or a source and/or a drain of multiple devices. The source/drain contacts 128 include common source/drain contacts. For example, FIG. 3 shows a first common source/drain contact 130 that couples together source/drains of the second pull-up transistor PU2 and the second pull-down transistor PD2, a second common source/drain contact 132 that couples together source/drains of two adjacent pull-down transistors, a third common source/drain contact 134 couples together source/drains of a pull-up transistor and a pull-down transistor of the SRAM cell across the second mirror axis MA2 from the SRAM cell 10, and a fourth common source/drain contact 136 that couples together source/drains of a pull-up transistor and a pull-down transistor of the SRAM cell across the second mirror axis MA2 from the SRAM cell 10. In the depicted embodiment, the frontside interconnect layer 140 further includes gate vias 144 disposed over and connected to the gate structure (e.g., the gate structures 20 and 26) and device vias 146 disposed over and connected to the source/drain contacts 128 including the common source/drain contacts.

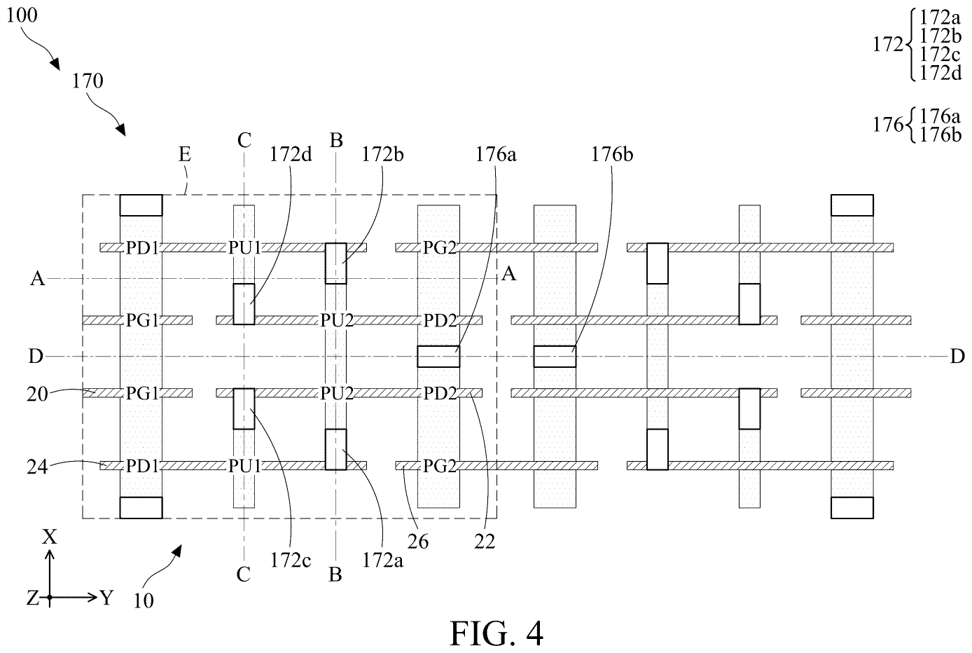

FIG. 4 illustrates a backside interconnect layer 170 of the quad-cell 100. In the depicted embodiments, the backside interconnect layer 170 includes backside butted contacts 172a, 172b, 172c, and 172d, which may be collectively or individually referred to as backside butted contact(s) 172 as the context requires. The backside butted contact(s) 172 may provide local interconnect between gate structures and adjacent source/drain features. In the SRAM cell 10, the backside butted contact 172a couples a gate structure 24 of the first pull-up transistor PU1 to a source/drain of the second pull-up transistor PU2. In the SRAM cell above the SRAM cell 10, the backside butted contact 172b also couples a gate structure of the first pull-up transistor PU1 to a source/drain of the second pull-up transistor PU2. The backside butted contact 172c couples the gate structure 22 of the second pull-up transistor PU2 to a source/drain of the first pull-up transistor PU1. In the SRAM cell above the SRAM cell 10, the backside butted contact 172d also couples a gate structure of the second pull-up transistor PU2 to a source/drain of the first pull-up transistor PU1. In some implementations, the backside butted contacts 172 include a suitable metal, such as tungsten (W). The backside butted contacts 172 may be formed together with backside source/drain contacts (to be described).

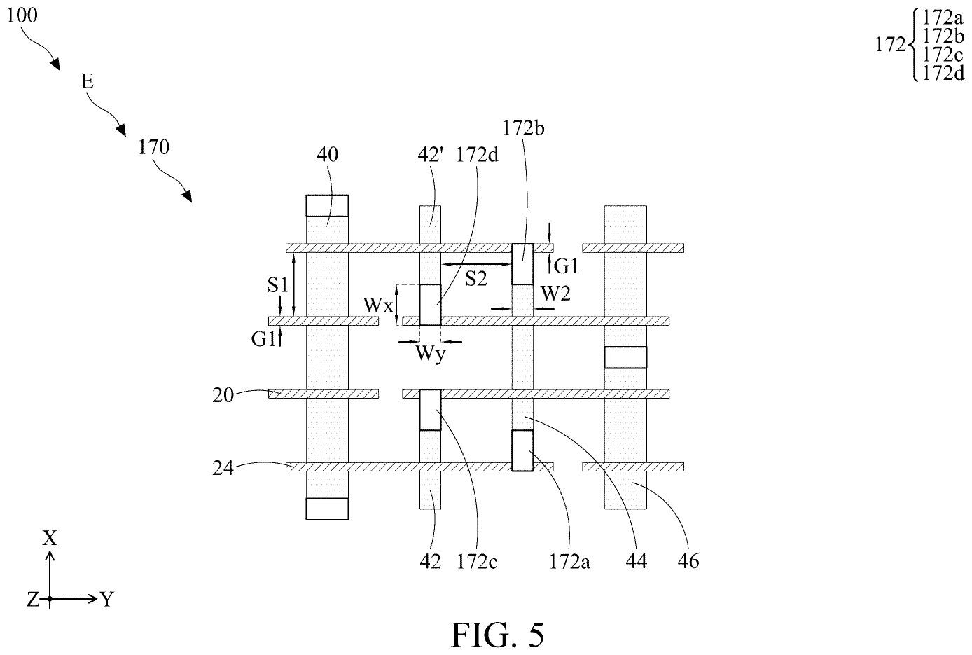

FIG. 5 illustrates an enlarged view of a portion E of the quad-cell 100 as in FIG. 4 and includes two SRAM cells. The gate structures each have a width G1 as depicted in the X direction. A gate-to-gate space in the X direction between two gate structures may be referred to as space S1. The backside butted contact 172 may have a width Wx in the X direction and a width Wy in the Y direction. The p-type active regions 42 and 44 each may have the width W2 in the Y direction as described above. A space in the Y direction between the p-type active regions 42 (or 42′) and 44 may be referred to as space S2. In some embodiments, a ratio of Wx to G1 is greater than about 1 and less than about 3. If the ratio is too small (e.g., less than about 1), the backside butted contact 172 may be too narrow to contact both the source/drain region and the gate structure. If the ratio is too large (e.g., greater than about 3), the backside butted contact 172 may further contact an adjacent gate structure, resulting in an undesired bridge. In some embodiments, a ratio of Wy to W2 is greater than about 1 and less than about 4. If the ratio is too small (e.g., less than about 1), the backside butted contact 172 may contact a too small area of the source/drain. If the ratio is too large (e.g., greater than about 4), the backside butted contact 172 may further contact an adjacent backside butted contact 172, resulting in an undesired bridge. A ratio of S2 to Wy may be greater than about 3 and less than about 6. If the ratio is too small (e.g., less than about 3), the space S2 between the p-type active regions 42 and 44 may be too small, the backside butted contact 172 may further contact an adjacent backside butted contact 172, resulting in an undesired bridge. If the ratio is too large (e.g., greater than about 6), Wy may be too small, the backside butted contact 172 may contact a too small area of the source/drain.

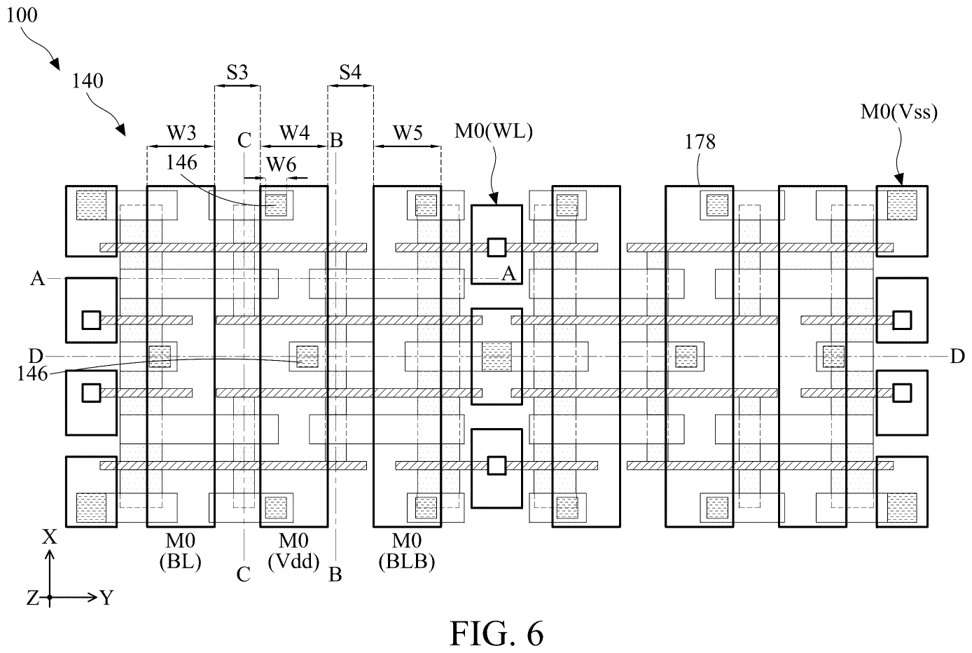

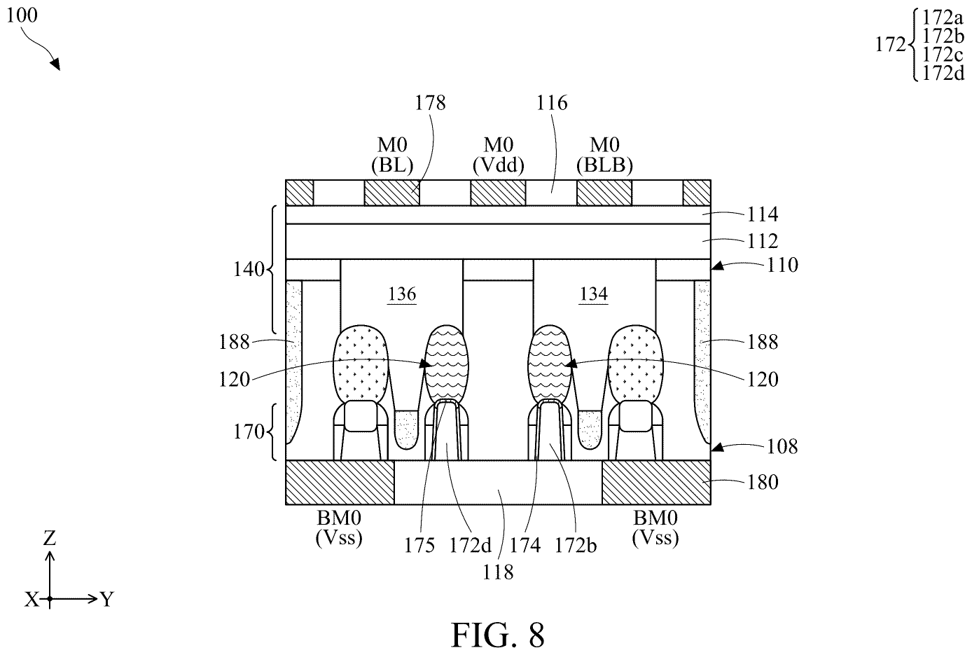

FIG. 6 illustrates the frontside interconnect layer 140 of the quad-cell 100, and a frontside interconnect structure over the frontside interconnect layer 140. The frontside interconnect structure may include frontside dielectric layers (e.g., first frontside dielectric layers) and conductive features (e.g., metal lines, metal vias) embedded in the frontside dielectric layers. The frontside dielectric layers may include SiO, SiN, SiON, tetraethylorthosilicate (TEOS) formed oxide, phosphosilicate glass (PSG), borophosphosilicate glass (BPSG), low-k dielectric material (K<3.9), other suitable dielectric material, or combinations thereof. In some embodiments, the frontside interconnect structure includes a first frontside metal layer, also referred to as M0 metal layer embedded in first frontside dielectric layers 116 as in FIG. 8. The M0 metal layer may include M0 metal lines 178. The M0 metal lines 178 may be connected to the conductive features (e.g., the gate vias 144, the device vias 146) in the frontside interconnect layer 140. The M0 metal lines 178 may carry various voltages and/or signals. The M0 metal lines 178 may include M0 bit line (BL), M0 bit line bar (BLB), M0 Vdd line (M0(Vdd)), M0 Vss line (M0 (Vss)), and M0 word line (WL).

In the depicted embodiments of FIG. 6, there is no frontside butted contact in the frontside interconnect layer 140 of the quad-cell 100, thus more space in the first dielectric layers is available for the M0 metal lines 178, more flexibility is provided to the M0 metal lines 178, and M0 metal lines 178 (e.g., M0 (Vdd), M0 (BLB), M0 (BL)) may have increased widths in the Y direction and thus have reduced resistances. In such embodiments, M0 (Vdd) may have a rectangular shape in the top view. In some embodiments, M0 (Vdd) has a first sidewall on one side extending continuously (e.g., in the X direction) over a region of the quad-cell 100, and a second sidewall on an opposite side extending continuously (e.g., in the X direction) over the region of the quad-cell 100. In some embodiments, M0 (BL), M0 (Vdd), M0 (BLB) have widths W3, W4, and W5 in the Y direction, respectively. The device via 146 has a width W6 in the Y direction. A space in the Y direction between M0 (BL) and M0 (Vdd) may be referred to as space S3, and a space in the Y direction between M0 (Vdd) and M0 (BLB) may be referred to as space S4. In some embodiments, W3 is equal to W5 for a purpose of operation symmetry. In some embodiments, S3 is equal to S4 for a purpose of operation symmetry. In some embodiments, W4 is equal to or greater than two times of W6, so that M0 (Vdd) may fully cover at least two of the device vias 146 in the Y direction. In some embodiments, W3 (or W5) is equal to or greater than W6, so that M0 (BL) or M0 (BLB) may fully cover at least one of the device vias 146 in the Y direction. In some embodiments, a ratio of W3 (or W5) to W4 is greater than about 0.2 and less than about 4. If the ratio is too small (e.g., less than about 0.2) or too large (e.g., greater than about 4), W4 is too large or W3 (or W5) is too large, respectively, M0 (Vdd) may be too close to M0 (BL) and/or M0 (BLB), which may cause electrical short therebetween.

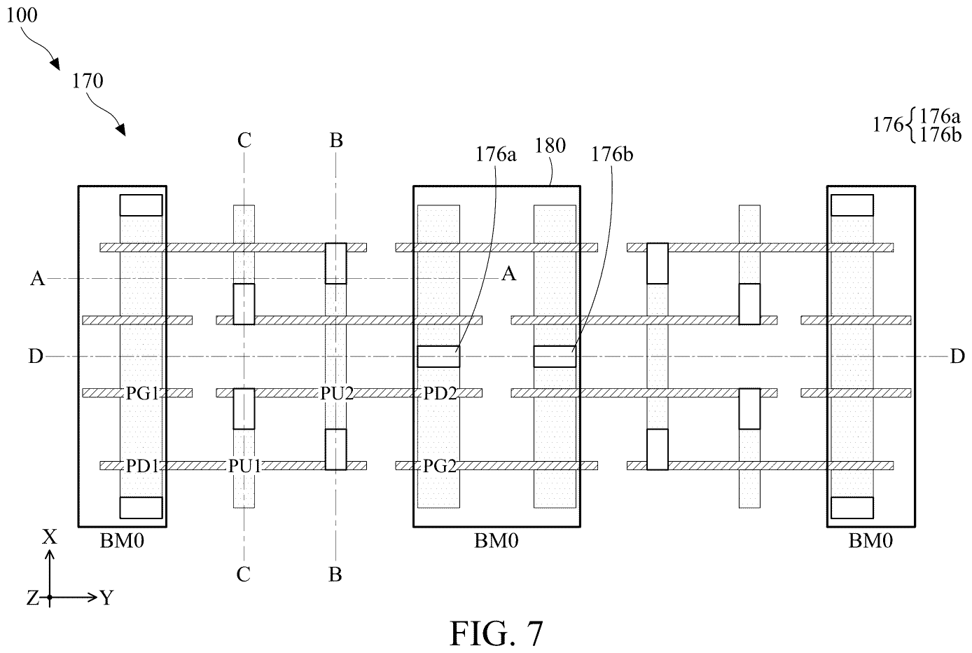

FIG. 7 illustrates the backside interconnect layer 170 of the quad-cell 100, and a backside interconnect structure below the backside interconnect layer 170. The backside interconnect structure may include backside dielectric layers (e.g., first backside dielectric layers) and backside conductive features (e.g., backside metal lines, backside metal vias) embedded in the backside dielectric layers. The backside dielectric layers may include similar materials as the frontside dielectric layers. In some embodiments, the backside interconnect structure includes a first backside metal layer, also referred to as BM0 metal layer embedded in first backside dielectric layers 118 as in FIG. 8. The BM0 metal layer may include BM0 metal lines 180 connected to the conductive features (e.g., backside source contacts 176, also referred to as backside source/drain contacts 176) in the backside interconnect layer 170. In some embodiments, the BM0 metal lines 180 are connected to the ground potential Vss and are referred to as backside ground rails 180.

The backside source contacts 176a and 176b connect source of pull-down transistors (including the second pull-down transistor PD2) to the backside ground rail 180. The backside source contacts 176a and 176b may include a suitable metal, such as tungsten (W). It is noted that sources of the first pull-up transistor PU1, the second pull-up transistor PU2, the first pass-gate transistor PG1, and the second pass-gate transistor PG2 are not coupled to conductive features (e.g., BM0 metal lines 180) in the backside interconnect structure by way of any counterpart of the backside source contacts 176.

FIG. 8 illustrates a fragmentary cross-sectional view of the quad-cell 100 along cross section A-A in FIGS. 3-4 and 6-7. Referring to FIG. 8, cross section A-A cuts through the third common source/drain contact 134, the fourth common contact 136, and the backside butted contacts 172b and 172d. As shown in FIG. 8, each of the backside butted contacts 172b and 172d engages a source/drain feature of a pull-up transistor, such as a source/drain feature 120. The backside butted contact 172 may interface the source/drain feature 120 by way of a silicide layer 175. In some embodiments, the silicide layer 175 may include a metal silicide, such as titanium silicide (TiSi), tungsten silicide (WSi), nickel silicide (NiSi), or cobalt silicide (CoSi). In some embodiments, a dielectric liner (e.g., a nitride liner) 174 is disposed on sidewalls of the backside butted contact 172. The fragmentary cross-sectional view in FIG. 8 also illustrates portions of gate cut features 188. The gate cut feature 188 may cut a continuous gate structure into segments and isolate the segments. For example, referring to FIGS. 3 and 8, the gate structure 22′ may be isolated from a gate structure in a mirror image SRAM cell across the first mirror axis MA1 by the gate cut feature 188. The gate cut features 188 may include silicon nitride, silicon oxide, silicon oxynitride, silicon oxycarbonitride, silicon oxycarbide, silicon carbonitride, or a combination thereof.

In some embodiments, the source/drain contacts (e.g., the common source/drain contacts 134 and 136) are embedded in a plurality of dielectric layers, such as first dielectric layers 108 and second dielectric layers 110. Each of the first dielectric layers 108 and the second dielectric layers 110 may include a contact etch stop layer (CESL) and an interlayer dielectric (ILD) layer. The CESL and the ILD layer may include different dielectric materials. In some embodiments, the CESL includes silicon nitride and the ILD layer includes silicon oxide. In some embodiments, a second CESL layer 112 and a second ILD layer 114 are disposed over the source/drain contacts.

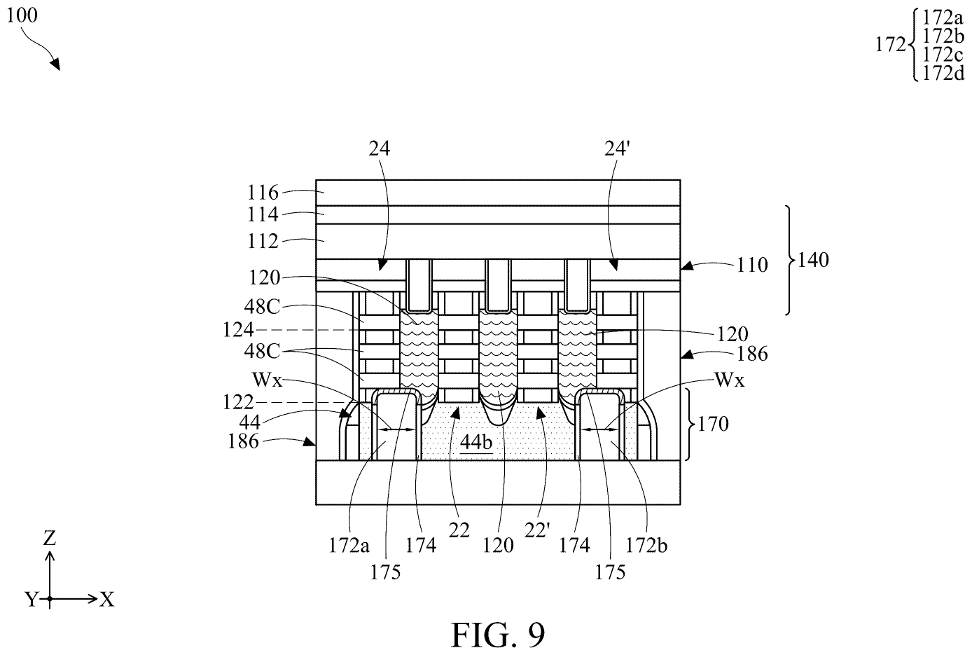

FIG. 9 illustrates a fragmentary cross-sectional view of the quad-cell 100 along cross section B-B in FIGS. 3-4 and 6-7. Referring to FIG. 9, cross section B-B cuts through two source/drain features 120 of the second pull-up transistor PU2, a source/drain feature 120 of the pull-up transistor in the mirror SRAM cell of the SRAM cell 10 across the second mirror axis MA2, gate structures 22 and 24, gate structures 22′ and 24′ in the mirror SRAM cell of the SRAM cell 10 across the second mirror axis MA2, the backside butted contacts 172a and 172b. As shown in FIG. 9, the backside butted contact 172a is electrically coupled to the gate structure 24 and the adjacent source/drain feature 120, and the backside butted contact 172b is electrically coupled to the gate structure 24′ and the adjacent source/drain feature 120. It can be seen that along the X direction, each of the backside butted contacts 172a and 172b has the width Wx as described above to engage a gate structure (24 or 24′) and an adjacent source/drain feature 120.

In some embodiments as depicted in FIG. 9, the backside butted contacts 172a and 172b extend into the adjacent source/drain feature 120 and the respective gate structure. A top surface of the backside butted contacts 172a and 172b may be between a level 122 of a topmost surface of the base portion (e.g., a base portion 44b) of the active regions (e.g., the active region 44), and a level 124 of a bottom surface of a topmost channel member 48C. If the top surface of the backside butted contacts 172 is too low (e.g., below the level 122), the backside butted contacts 172 may not contact the adjacent source/drain feature 120 and/or the respective gate structure. If the top surface of the backside butted contacts 172 is too high (e.g., above the level 124), too much source/drain features 120 may be etched in forming the backside butted contacts 172. In the depicted embodiment, the backside butted contact 172 interfaces the adjacent source/drain 120, the respective gate structure (e.g., the gate structure 24 or 24′), and the adjacent channel member 48C by the silicide layer 175. FIG. 9 further illustrates portions of fin cut features 186. In some embodiments, a fin cut features 186 cuts a continuous active region into segments and isolates the segments. The fin cut features 186 may include silicon nitride, silicon oxide, silicon oxynitride, silicon oxycarbonitride, silicon oxycarbide, silicon carbonitride, or a combination thereof. The channel members 48C connected to a fin cut feature may be referred to as dummy channel members 48C or dummy semiconductor layers 48C.

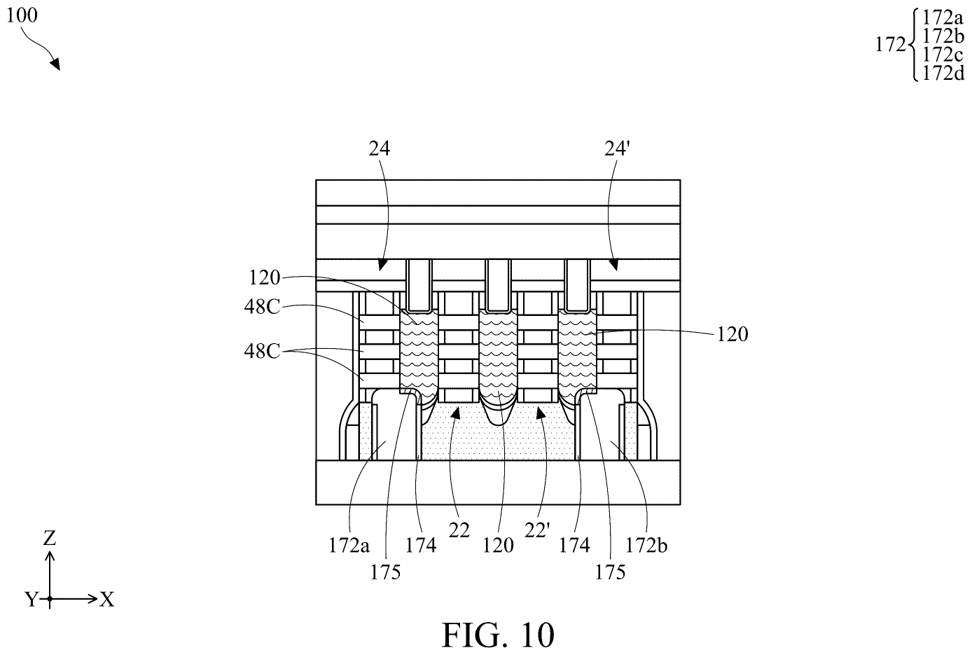

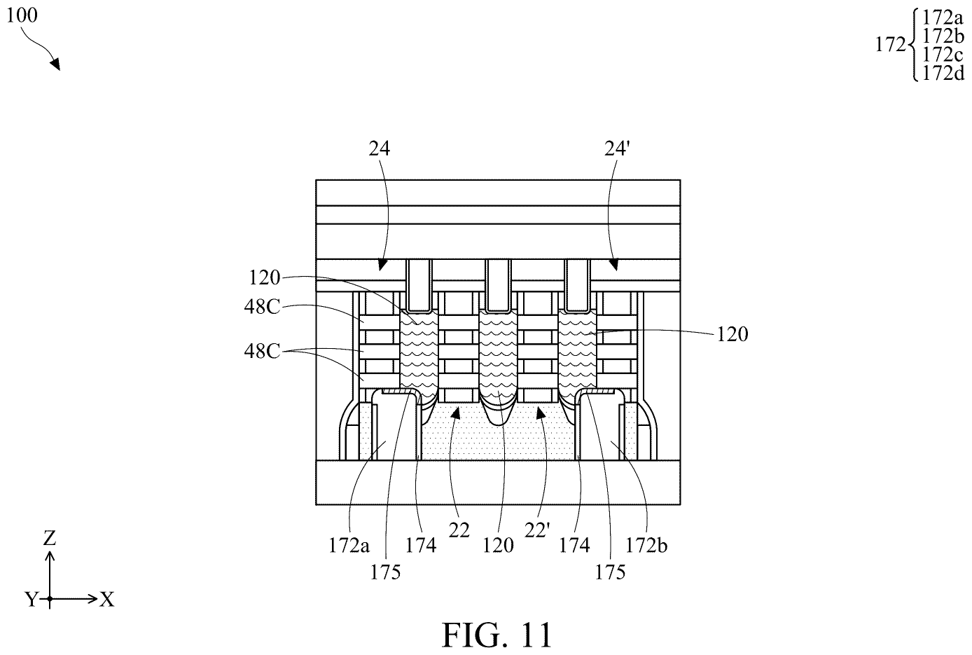

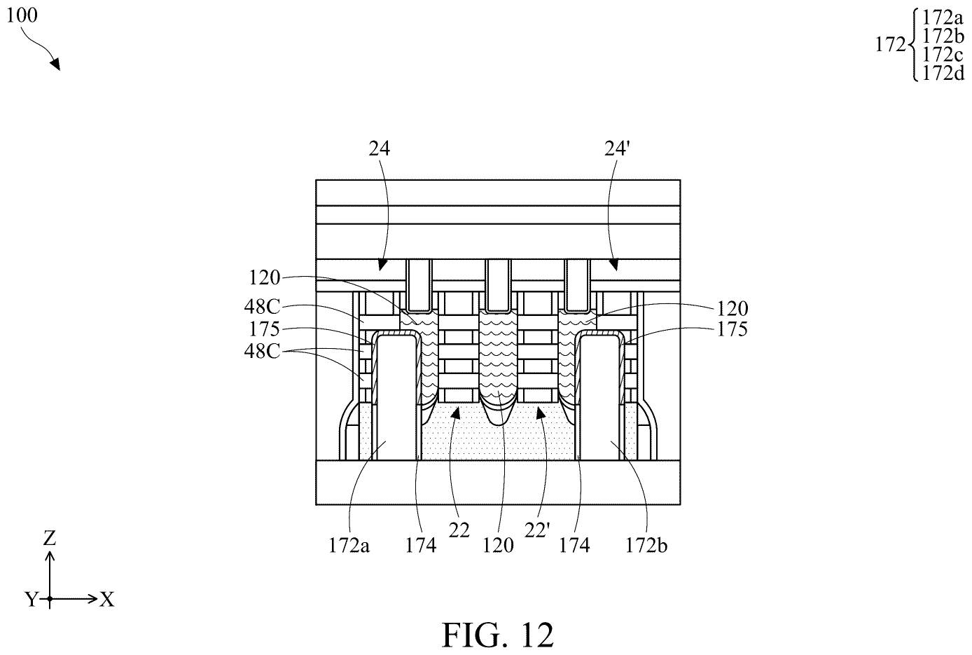

FIGS. 10-12 illustrate alternative fragmentary cross-sectional views of the quad-cell 100 along cross section B-B in FIGS. 3-4 and 6-7. Referring to FIG. 10, in some embodiments, the backside butted contact 172 interfaces the adjacent source/drain feature 120 by way of the silicide layer 175 and directly contacts the respective gate structure (e.g., the gate structure 24 or 24′) and the adjacent channel member 48C. Referring to FIG. 11, in some embodiments, the backside butted contact 172 interfaces the adjacent source/drain feature 120 and the adjacent channel member 48C by way of the silicide layer 175 and directly contacts the respective gate structure (e.g., the gate structure 24 or 24′). Referring to FIG. 12, in some embodiments, the backside butted contact 172 extends through one or more channel members 48C. In the depicted embodiment, the backside butted contact 172 interfaces the adjacent source/drain 120, the respective gate structure (e.g., the gate structure 24 or 24′), and the adjacent channel member 48C by the silicide layer 175. In some other embodiments, the silicide layer 175 may be disposed similarly to embodiments represented by FIGS. 10 and 11. When the backside butted contact 172 interfaces the adjacent source/drain feature 120 and the adjacent channel members 48C by way of the silicide layer 175 and directly contacts the respective gate structure (e.g., the gate structure 24 or 24′), the silicide layer 175 may be discontinuous because the channel members 48C are interleaved by the respective gate structure.

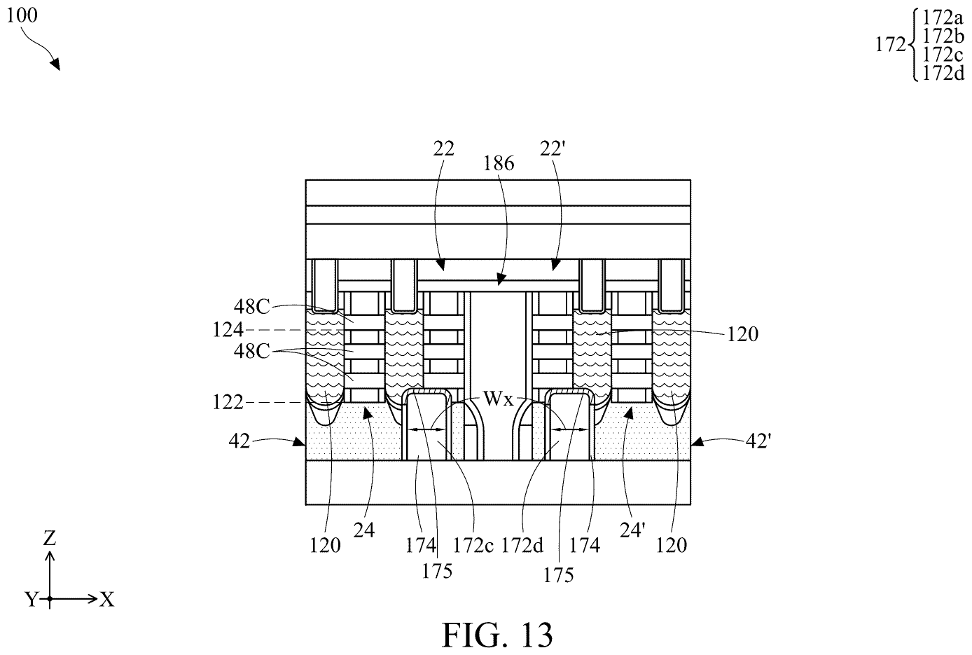

FIG. 13 illustrates a fragmentary cross-sectional view of the quad-cell 100 along cross section C-C in FIGS. 3-4 and 6-7. Cross section C-C cuts through source/drain features 120 of the first pull-up transistor PU1, source/drain features 120 of the first pull-up transistor in the mirror SRAM cell of the SRAM cell 10 across the second mirror axis MA2, the gate structures 22, 24, 22′, and 24′, and the backside butted contacts 172c and 172d. As shown in FIG. 13, the backside butted contact 172c is electrically coupled to the gate structure 22 and the adjacent source/drain feature 120, and the backside butted contact 172d is electrically coupled to the gate structure 22′ and the adjacent source/drain feature 120. The backside butted contacts 172c and 172d may be similar to the backside butted contacts 172a and 172b as described above. For example, a top surface of the backside butted contacts 172c and 172d may be between the level 122 and 124. A difference includes that the backside butted contacts 172a, 172b, 172c, and 172d are electrically coupled to different gate structures and source/drains. The silicide layer 175 and the dielectric liner 174 on the backside butted contacts 172c and 172d may be similar to those described above with respect to FIGS. 9-12.

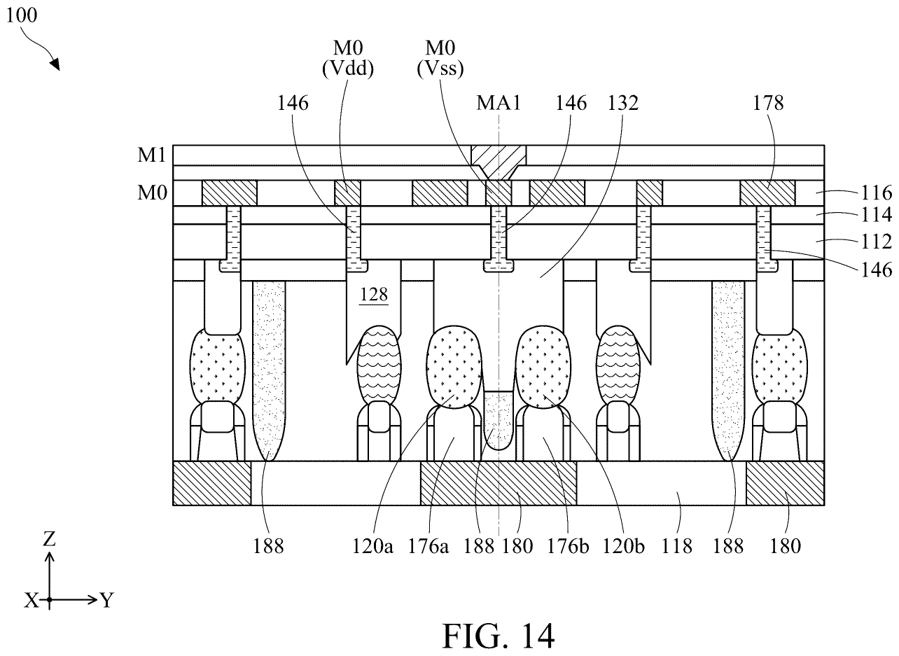

FIG. 14 illustrates a fragmentary cross-sectional view of the quad-cell 100 along cross section D-D in FIGS. 3-4 and 6-7. The mirror image placement of the SRAM cells in the quad-cell 100 allows a source/drain feature 120 of the second pull-down transistor PD2 to be placed next to a source/drain feature 120 of a pull-down transistor in an SRAM cell adjacent to the SRAM cell 10. For clarity purposes, the source/drain features 120 are herein referred to as a source 120a and a source 120b, respectively. In some embodiments, the backside source contacts 176a and 176b are connected to the sources 120a and 120b, respectively, and directly land on the backside ground rail 180. FIG. 14 also illustrates a second frontside metal layer (or MI metal layer) of the frontside interconnect structure and disposed over the first frontside metal layer (or M0 metal layer). An MI metal line of the MI metal layer is connected to the M0 (Vss) above the second common source/drain contact 132. In some embodiments represented in FIG. 14, the sources 120a and 120b are coupled to the ground potential Vss not only through the second common contact 132 but also through the backside source contacts 176a and 176b. The additional electrical grounding provided by the backside source contacts 176a and 176b enables a higher saturation current for the second pull-down transistor PD2. Because the sources of the pass-gate transistors are not coupled to additional backside metal lines, saturation currents of the pass-gate transistors are kept low. The greater saturation current of the pull-down transistors help keep a beta (β) ratio of the SRAM cell 10 greater than 1, which allows the SRAM cell 10 have good read stability. The lower saturation current of the pass-gate transistors help keep an alpha (α) ratio of the SRAM cell high, which allows the SRAM cell 10 to have good writability. The fragmentary cross-sectional view in FIG. 14 also illustrates the gate cut features 188. Referring to FIGS. 3 and 14, the gate cut feature 188 in the left of FIG. 14 isolates the gate structures 20 and 22. The gate cut feature 188 in the middle of FIG. 14 isolates the gate structure 22 from a gate structure in a mirror image SRAM cell across the first mirror axis MA1. The gate cut feature 188 in the right of FIG. 14 is a mirror image of the gate cut feature 188 in the left of FIG. 14 and serves a similar function.

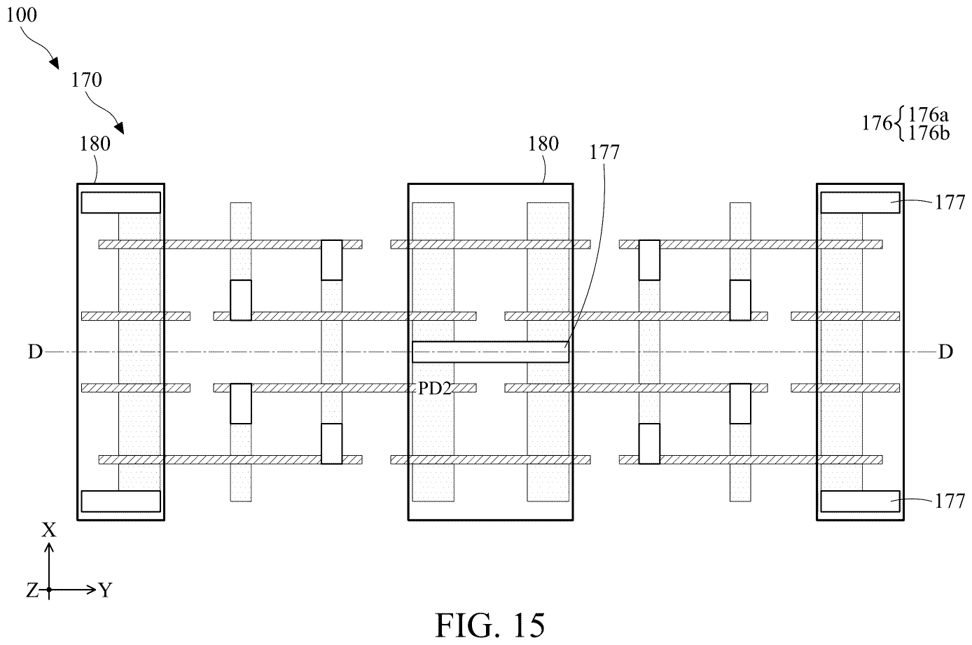

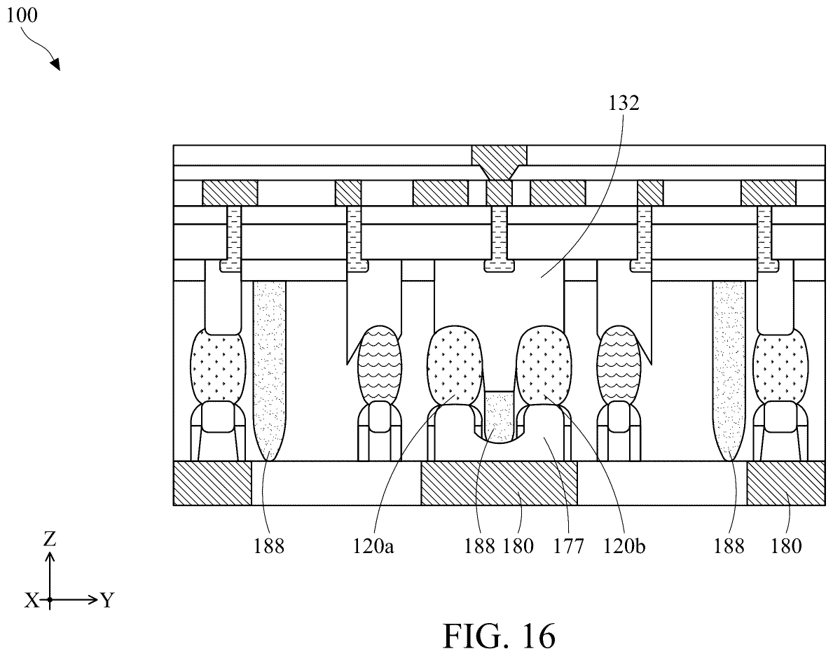

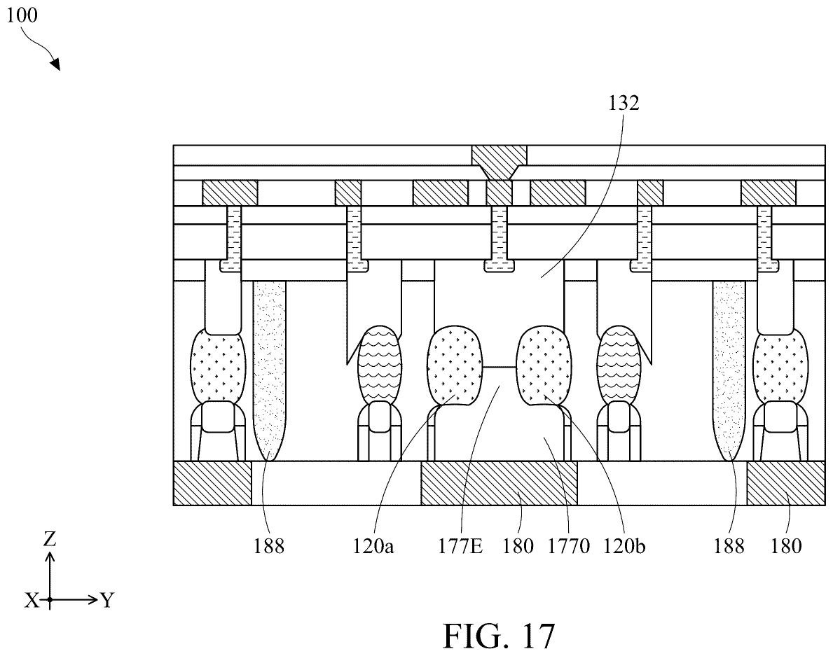

FIGS. 15-17 illustrate various aspects of example embodiments where two adjacent backside source/drain contacts (e.g., 176a, 176b) merge to form a backside bar contact so as to reduce contact resistance. Differences from the embodiments described above with respect to FIGS. 3-14 include follows. Like FIG. 7, FIG. 15 illustrates the backside interconnect layer 170 of the quad-cell 100, and the backside interconnect structure below the backside interconnect layer 170. Different from FIG. 7, FIG. 15 illustrates a backside bar contact 177. The backside bar contact 177 is structurally similar to backside source contacts 176a and 176b that are partially merged. As shown in FIGS. 15-16, the backside bar contact 177 spans below the sources 120a and 120b of the two adjacent pull-down transistors (e.g., PD2) of two adjacent SRAM cells. In some embodiments represented in FIG. 16, the backside bar contact 177 extends through a portion of the gate cut feature 188 in the middle. As shown in FIG. 16, the backside bar contact 177 has an enlarged interface with the underlying backside ground rail 180. Because a cross-sectional area of the conductive path is inversely related to the resistance, the enlarged interface provided by the backside bar contact 177 may effectively reduce the contact resistance with the backside ground rail 180. In some embodiments represented in FIG. 17, because the etch process for forming the backside bar contact opening may etch the second gate cut feature 190 at a greater rate, a wrap-around backside bar contact 1770 may be formed. The wrap-around backside bar contact 1770 includes an extension 177E that extends between the source 120a and the source 120b. Compared to the backside bar contact 177 in FIG. 16, the wrap-around backside bar contact 1770 may have a larger contact area with the sources 120a and 120b. The backside bar contact 177 and the wrap-around backside bar contact 1770 may include tungsten (W).

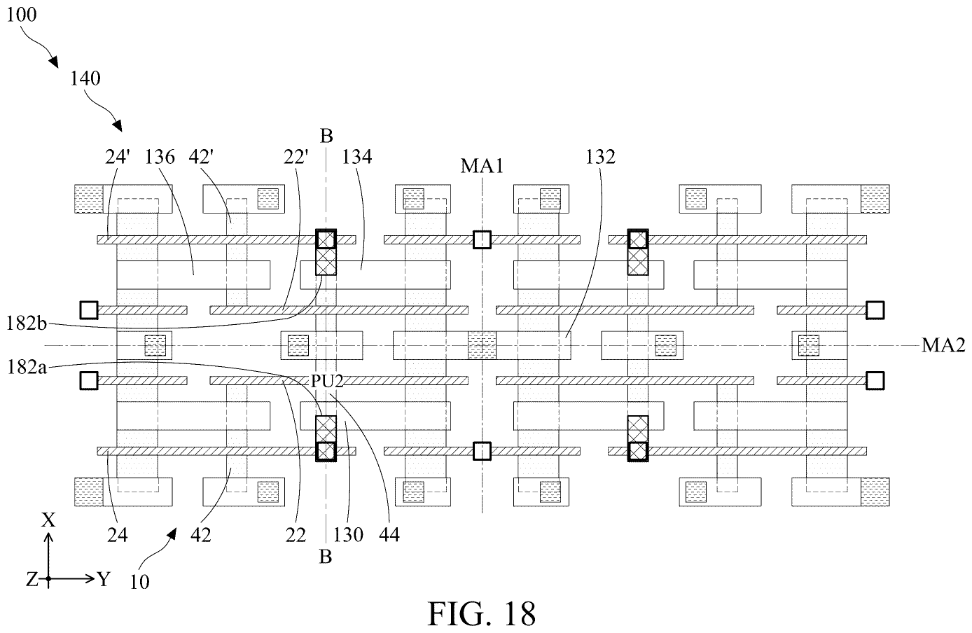

FIGS. 18-21 illustrate various aspects of example embodiments where the quad-cell 100 includes both backside butted contacts and frontside butted contacts. Differences from the embodiments described above with respect to FIGS. 3-14 include follows. In some embodiments, frontside butted contacts 182a and 182b replace the backside butted contacts 172a and 172b, respectively, while the backside butted contacts 172c and 172d remain. In some implementations, a vertical projection area of a frontside butted contact may substantially overlap with a vertical projection area of a backside butted contact it replaces. For example, a vertical projection area of the frontside butted contact 182a may substantially overlap with a vertical projection area of the backside butted contact 172a.

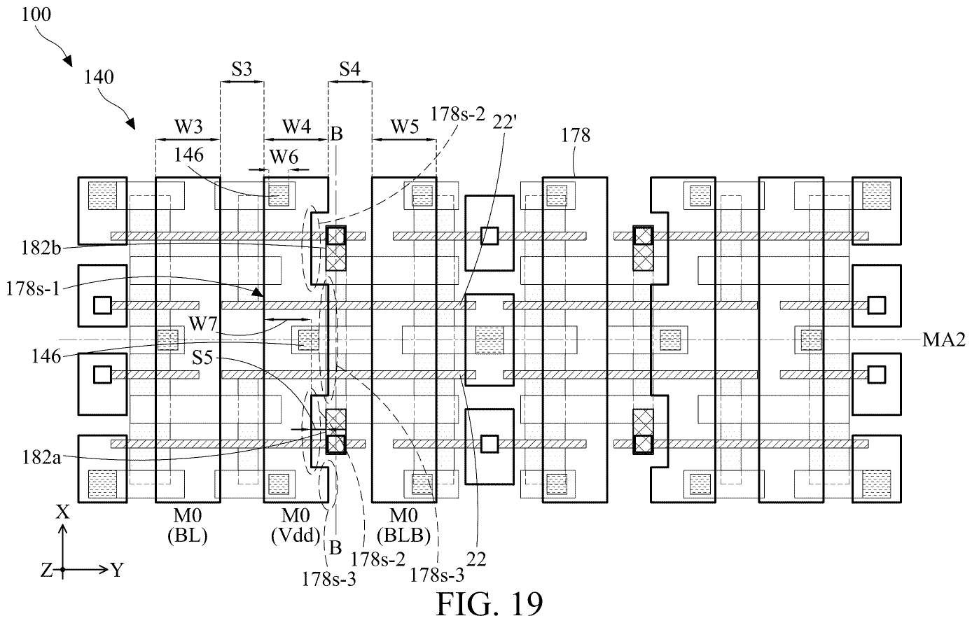

FIG. 19 illustrates a layout of the frontside interconnect layer 140 of the quad-cell 100, and the frontside interconnect structure over the frontside interconnect layer 140. Compared to FIG. 6, M0 (Vdd) in FIG. 19 has a first sidewall 178s-1 on a first side and second sidewalls on a second side opposite to the first side. The first sidewall 178s-1 extends continuously in the X direction. Along the X direction, the second sidewalls include interleaving recessed portions 178s-2 and non-recessed portions 178s-3. The recessed portions 178s-2 face the frontside butted contacts (e.g., 182a and 182b). M0 (Vdd) has the width W4 in the Y direction between the first sidewall 178s-1 and the non-recessed portions 178s-3, and a width W7 in the Y direction between the first sidewall 178s-1 and the recessed portions 178s-2. W4 is greater than W7. In some embodiments, a space in the Y direction between a recessed portion 178s-2 and an adjacent frontside butted contact (e.g., 182a) is S5. In some embodiments, a difference between W4 and S5 (i.e., W4-S5) is equal to or greater than W6. Thus, a recessed portion of M0 (Vdd) (e.g., a portion of M0 (Vdd) having a recessed portion 178s-2 as a sidewall) may fully cover at least one of the device vias 146 in the Y direction. The difference between W4 and S5 may be about the same as W7. Other dimensions (e.g., W3, W4, W5, W6, S3, and S4) and their relationships are similar as described above. The M0 metal lines over the quad-cell 100 may be symmetric with respect to the first mirror axis MA1 and the second mirror axis MA2. A single M0 (Vdd) is asymmetric with respect to any line along the X direction and is symmetric with respect to the second mirror axis MA2. For example, a line of symmetry of the single M0 (Vdd) may be the second mirror axis MA2 and may not be a line along the X direction.

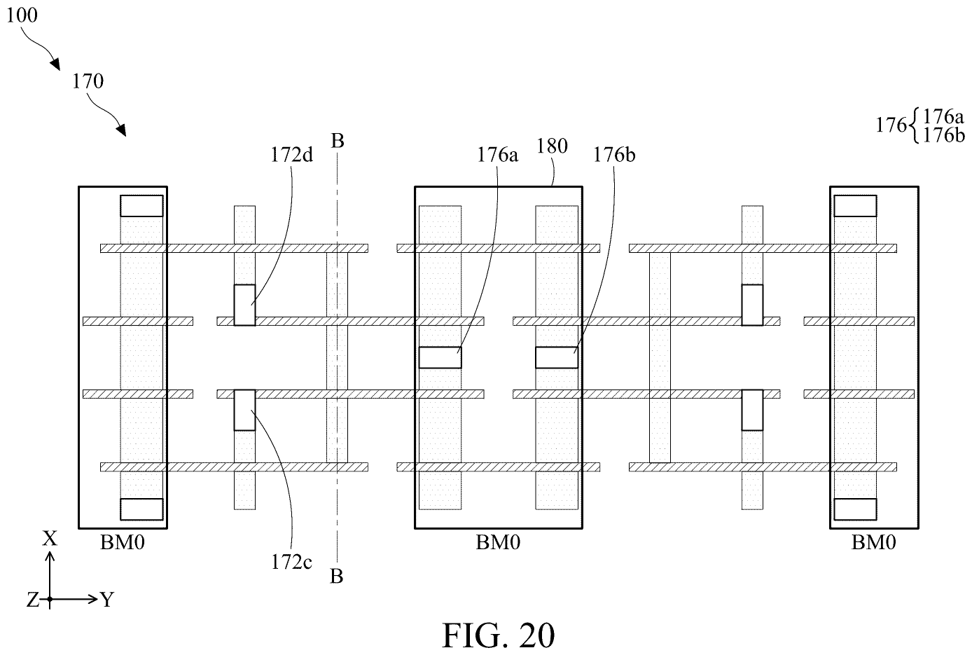

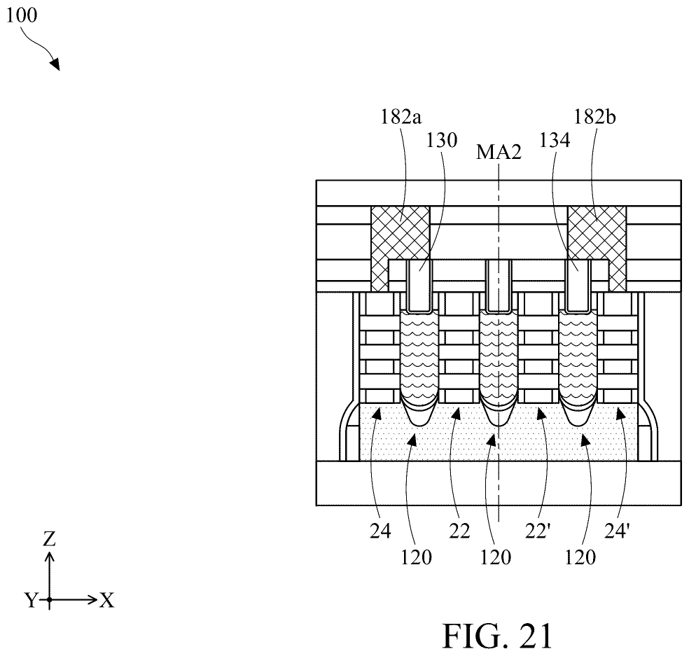

FIG. 21 illustrates a fragmentary cross-sectional view of the quad-cell 100 along cross section B-B in FIGS. 18-20. Cross section B-B cuts through the two source/drain features 120 of the second pull-up transistor PU2, a source/drain feature 120 of the pull-up transistor in the mirror SRAM cell of the SRAM cell 10 across the second mirror axis MA2, the gate structures 22, 24, 22′, and 24′, and the frontside butted contacts 182a and 182b. As shown in FIG. 21, the frontside butted contact 182a is electrically coupled to the gate structure 24 and the adjacent source/drain feature 120 (e.g., by the first common source/drain contact 130), and the frontside butted contact 182b is electrically coupled to the gate structure 24′ and the adjacent source/drain feature 120 (e.g., by the third common source/drain contact 134). Each of the frontside butted contacts (e.g., 182a and 182b) engages a gate structure (24 or 24′) and an adjacent source/drain feature 120. Referring to FIG. 20, in some embodiments, the backside source contacts 176a and 176b may be replaced by a backside bar contact 177 or a wrap-around backside bar contact 1770 as described above with respect to FIGS. 15-17.

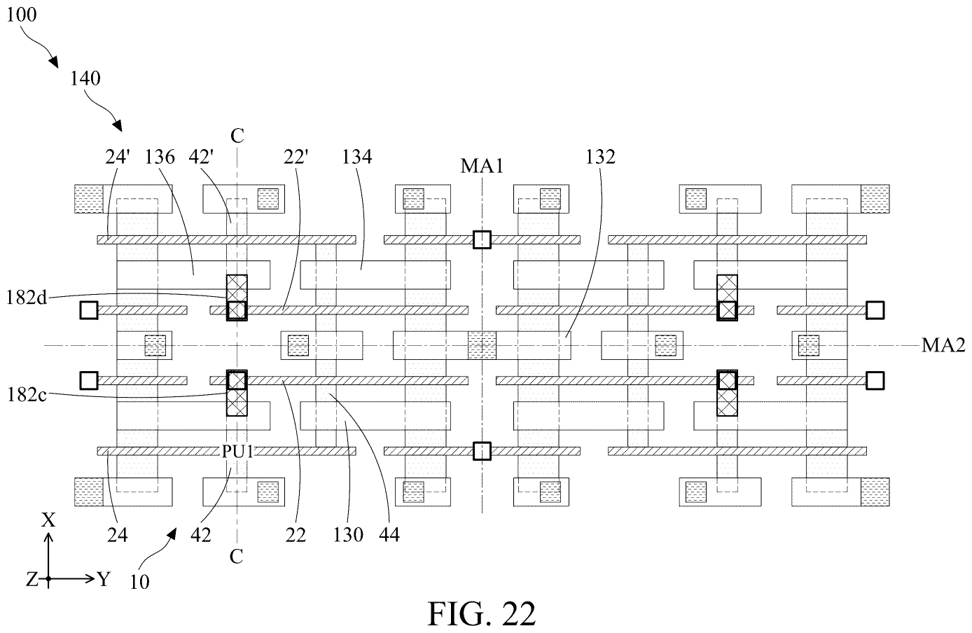

FIGS. 22-25 illustrate various aspects of alternative example embodiments where the quad-cell 100 includes both backside butted contacts and frontside butted contacts. Differences from the embodiments described above with respect to FIGS. 3-14 include follows. In some embodiments, frontside butted contacts 182c and 182d replace the backside butted contacts 172c and 172d, respectively, while the backside butted contacts 172a and 172b remain. In some implementations, a vertical projection area of a frontside butted contact may substantially overlap with a vertical projection area of a backside butted contact it replaces. For example, a vertical projection area of the frontside butted contact 182c may substantially overlap with a vertical projection area of the backside butted contact 172c.

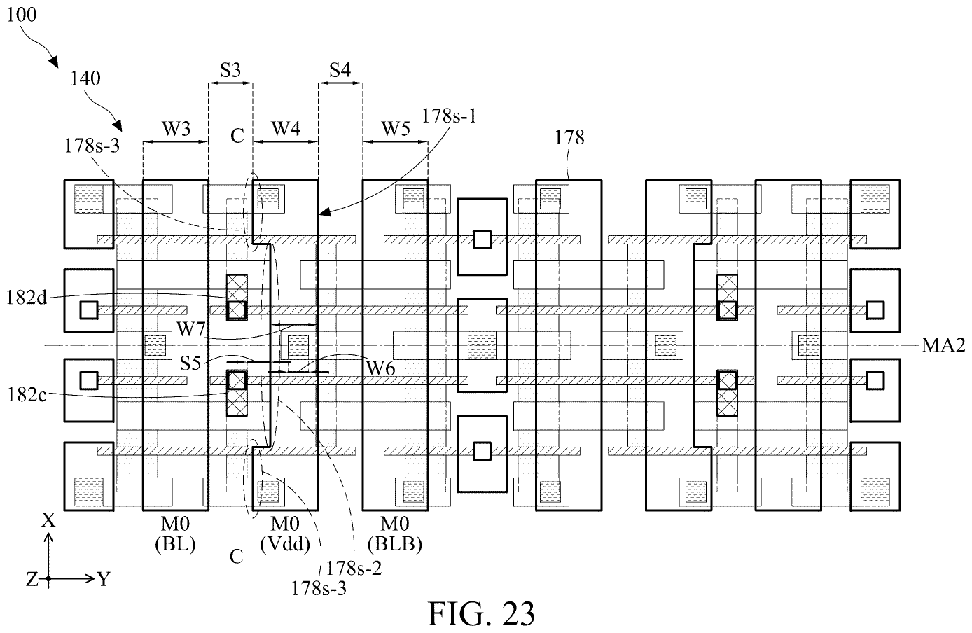

FIG. 23 illustrates a layout of the frontside interconnect layer 140 of the quad-cell 100, and the frontside interconnect structure over the frontside interconnect layer 140. Compared to FIG. 6, M0 (Vdd) in FIG. 20 has a first sidewall 178s-1 on a first side and second sidewalls on a second side opposite to the first side. The first sidewall 178s-1 extends continuously in the X direction. Along the X direction, the second sidewalls include interleaving recessed portion 178s-2 and non-recessed portions 178s-3. The recessed portion 178s-2 faces the frontside butted contacts (e.g., 182c and 182d). M0 (Vdd) has the width W4 in the Y direction between the first sidewall 178s-1 and the non-recessed portions 178s-3, and the width W7 in the Y direction between the first sidewall 178s-1 and the recessed portion 178s-2. W4 is greater than W7. In some embodiments, a space in the Y direction between a recessed portion 178s-2 and an adjacent frontside butted contact (e.g., 182c) is S5. In some embodiments, a difference between W4 and S5 (i.e., W4-S5) is equal to or greater than W6. Thus, a portion of M0 (Vdd) may fully cover at least one of the device vias 146 along the Y direction. The difference between W4 and S5 may be about the same as W7. Other dimensions (e.g., W3, W4, W5, W6, S3, and S4) and their relationships are similar as described above. The M0 metal lines over the quad-cell 100 are symmetric with respect to the first mirror axis MA1 and the second mirror axis MA2. A single M0 (Vdd) is asymmetric with respect to any line along the X direction and is symmetric with respect to the second mirror axis MA2. For example, a line of symmetry of the single M0 (Vdd) may be the second mirror axis MA2 and may not be a line along the X direction.

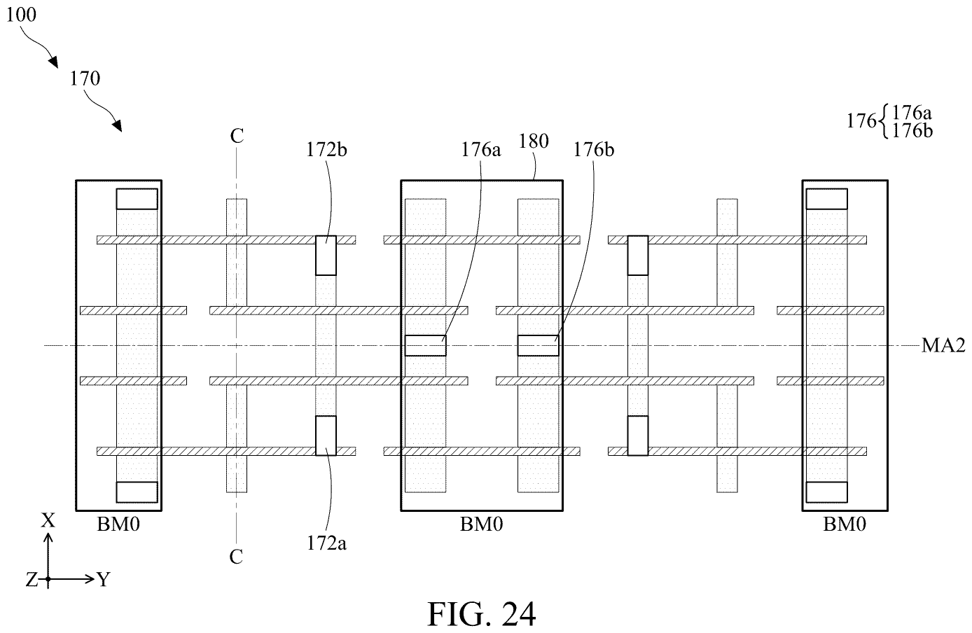

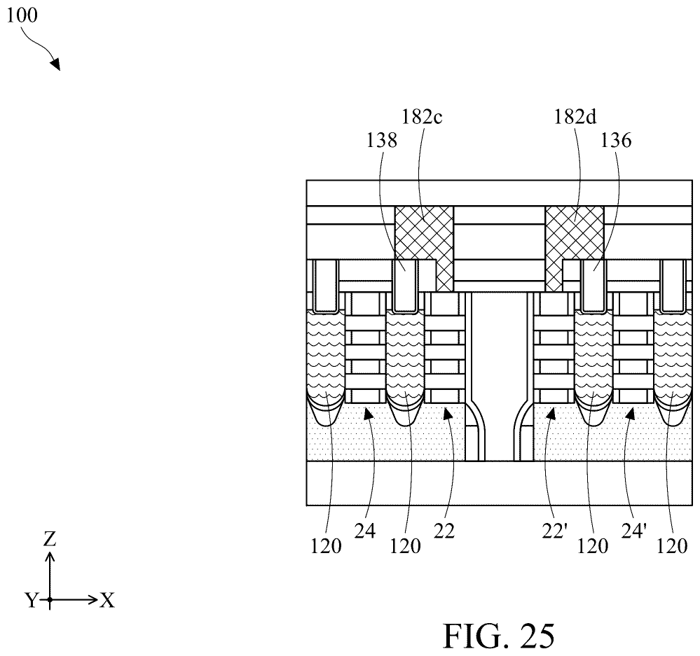

FIG. 25 illustrates a fragmentary cross-sectional view of the quad-cell 100 along cross section C-C in FIGS. 22-24. Cross section C-C cuts through the two source/drain features 120 of the first pull-up transistor PU1, two source/drain features 120 of the pull-up transistor in the mirror SRAM cell of the SRAM cell 10 across the second mirror axis MA2, the gate structures 22, 24, 22′, and 24′, and the frontside butted contacts 182c and 182d. As shown in FIG. 25, the frontside butted contact 182c is electrically coupled to the gate structure 22 and the adjacent source/drain feature 120 (e.g., by a fifth common source/drain contact 138), and the frontside butted contact 182d is electrically coupled to the gate structure 22′ and the adjacent source/drain feature 120 (e.g., by the fourth common source/drain contact 136). Each of the frontside butted contacts (e.g., 182c and 182d) engages a gate structure (22 or 22′) and an adjacent source/drain feature 120. Referring to FIG. 24, in some embodiments, the backside source contacts 176a and 176b may be replaced by a backside bar contact 177 or a wrap-around backside bar contact 1770 as described above with respect to FIGS. 15-17.

In the embodiments represented by FIGS. 18-25, by replacing some of the backside butted contacts (e.g., 172a and 172b, or 172c and 172d, shown in FIG. 4), flexibility is provided to both the frontside interconnect structure (e.g., M0 metal lines) and the backside interconnect layer 170, while having operation symmetry (e.g., with respect to the SRAM cell 10 and the SRAM cell across the second mirror axis MA2 from the SRAM cell 10), thus having device performance balance and reducing impact to the performance of the quad-cell 100. The some of the backside butted contacts that are replaced by the frontside butted contacts are not randomly chosen, but are specifically configured to achieve the benefits and performance of the quad-cell 100 described above.

Although FIGS. 1-25 illustrate semiconductor structures having SRAM cells based on six GAA transistors (6T), other examples of semiconductor devices (e.g., having SRAM cells based on 7-transistor (7T), 8-transistor (8T), 9-transistor (9T), 10-transistor (10T), 11-transistor (11T), or 12-transistor (12T) technologies, having other types of transistors, such as planar, FinFET, and nanowire transistors) may benefit from aspects of the present disclosure.

Although not intended to be limiting, one or more embodiments of the present disclosure provide many benefits to a semiconductor structure. For example, by having backside butted contacts to engage selected gate structures and source/drain features, more space may be available for the M0 metal lines in the frontside interconnect structure. M0 metal line for a power voltage Vdd may be wider to reduce resistance and to enhance Vmax. Thus, the overall performance of the semiconductor device may be improved.

In one exemplary aspect, the present disclosure is directed to a semiconductor structure. The semiconductor structure includes an active region. The active region includes a semiconductor fin base, a stack of nanostructures over the semiconductor fin base, and an epitaxial feature over the semiconductor fin base and connected to at least one of the nanostructures. The active region extends lengthwise in a first direction. The semiconductor structure further includes a gate structure wrapping around each of the nanostructures, the gate structure extending lengthwise in a second direction perpendicular to the first direction. The semiconductor structure further includes a backside butted contact disposed directly under and electrically connected to the epitaxial feature and the gate structure. A portion of the backside butted contact extends into the gate structure and the epitaxial feature.

In some embodiments, a top surface of the backside butted contact is above a top surface of the semiconductor fin base and below a bottom surface of a topmost nanostructure, the top surface of the semiconductor fin base interfaces with the gate structure. In some embodiments, the semiconductor structure further includes a silicide layer disposed between the epitaxial feature and the backside butted contact. In some embodiments, the silicide layer is further disposed between the gate structure and the backside butted contact. In some embodiments, the epitaxial feature is disposed on a first side of the stack of nanostructures, and the semiconductor structure further includes an isolation structure connected to the stack of nanostructures and disposed on a second side of the stack of nanostructures, the second side being opposite to the first side. In some embodiments, the gate structure is a first gate structure, and the stack of nanostructures is a first stack of first nanostructures, the active region further includes a second stack of second nanostructures over the semiconductor fin base and connected to the epitaxial feature, the semiconductor structure further includes a second gate structure wrapping around each of the second nanostructures in forming a pull-up transistor of a memory cell.

In another exemplary aspect, the present disclosure is directed to a semiconductor structure. The semiconductor structure includes a static random-access memory (SRAM) cell and an interconnect structure disposed over the SRAM cell. The SRAM cell includes a first active region and a first portion of a second active region extending lengthwise along a first direction, a first metal gate stack intersecting the first active region in forming a first pull-up transistor of the SRAM cell, the first metal gate stack extending lengthwise along a second direction perpendicular to the first direction, a second metal gate stack intersecting the first portion of the second active region in forming a second pull-up transistor of the SRAM cell, a first contact feature disposed below and connected with a first source/drain region of the first pull-up transistor and the second metal gate stack, and a second contact feature disposed below and connected with a second source/drain region of the second pull-up transistor and the first metal gate stack. The interconnect structure includes a metal line connected to a third source/drain region of the first pull-up transistor and a fourth source/drain region of the second pull-up transistor by vias and source/drain contacts under the vias, in a top view, the metal line has continuous sidewalls extending lengthwise along the first direction.

In some embodiments, the first contact feature extends into the first source/drain region of the first pull-up transistor and the second metal gate stack, and the second contact feature extends into the second source/drain region of the second pull-up transistor and the first metal gate stack. In some embodiments, the metal line has a first width in the second direction, the vias each have a second width in the second direction, the first width is equal to or greater than two times of the second width. In some embodiments, the SRAM cell is a first SRAM cell, the semiconductor structure further includes a second SRAM cell being a mirror image of the first SRAM cell with respect to a first symmetry line in the second direction. The second SRAM cell includes a third active region and a second portion of the second active region extending lengthwise along the first direction, the first and second portions of the second active region being continuous, a third metal gate stack intersecting the second portion of the second active region in forming a third pull-up transistor of the second SRAM cell, a fourth metal gate stack intersecting the third active region in forming a fourth pull-up transistor of the second SRAM cell, a third contact feature disposed below and connected with a fifth source/drain region of the third pull-up transistor and the fourth metal gate stack, and a fourth contact feature disposed below and connected with a sixth source/drain region of the fourth pull-up transistor and the third metal gate stack. In some embodiments, the continuous sidewalls of the metal line extend over the second SRAM cell, and the metal line is electrically connected to a seventh source/drain region of the fourth pull-up transistor. In some embodiments, the first SRAM cell further includes a first pull-down transistor formed from a fourth active region and the second metal gate stack, the second SRAM cell further includes a second pull-down transistor formed from the fourth active region and the third metal gate stack, the first pull-down transistor and the second pull-down transistor share an eighth source/drain region, the semiconductor structure further includes a backside interconnect structure below the first SRAM cell and the second SRAM cell, the semiconductor structure includes a backside metal line disposed below the fourth active region and connected to the eighth source/drain region by a backside via. In some embodiments, the semiconductor structure further includes a third SRAM cell and a fourth SRAM cell being a mirror image of the first SRAM cell and the second SRAM cell with respect to a second symmetry line in the first direction, the backside via extends along the second direction to below the third SRAM cell and the fourth SRAM cell.

In yet another exemplary aspect, the present disclosure is directed to a semiconductor structure. The semiconductor structure includes a first gate structure, a second gate structure, a third gate structure, and a fourth gate structure extending lengthwise along a first direction, a first active region intersecting the first gate structure in forming a first pull-up transistor, a second active region intersecting the second gate structure and the third gate structure in forming a second pull-up transistor and a third pull-up transistor, respectively, a third active region intersecting the fourth gate structure in forming a fourth pull-up transistor, a first frontside butted contact disposed over and connected to the first gate structure and a second source/drain region of the second pull-up transistor, a second frontside butted contact disposed over and connected to the fourth gate structure and a third source/drain region of the third pull-up transistor, a first backside butted contact disposed below and connected to the second gate structure and a first source/drain region of the first pull-up transistor, and a second backside butted contact disposed below and connected to the third gate structure and a fourth source/drain region of the fourth pull-up transistor. The first active region, the second active region, and the third active region extend lengthwise along a second direction perpendicular to the first direction, and the first active region and the third active region align.

In some embodiments, the semiconductor structure further includes a frontside metal line disposed over the first gate structure, the second gate structure, the third gate structure, and the fourth gate structure, the frontside metal line extends lengthwise along the second direction, in a top view, the frontside metal line has a straight sidewall on a first side and second sidewalls on a second side opposite to the first side, the straight sidewall extends over the first gate structure, the second gate structure, the third gate structure, and the fourth gate structure, the second sidewalls include recessed portions facing the first frontside butted contact and the second frontside butted contact. In some embodiments, the frontside metal line is electrically connected to a fifth source/drain region of the first pull-up transistor, a sixth source/drain region of the second pull-up transistor, and a seventh source/drain region of the fourth pull-up transistor. In some embodiments, the semiconductor structure further includes a fourth active region extending lengthwise along the second direction and adjacent to the second active region, the second gate structure intersects with the fourth active region in forming a pull-down transistor, the semiconductor structure further includes a backside via below and connected to a fifth source/drain region of the pull-down transistor. In some embodiments, the semiconductor structure further includes a fifth active region extending lengthwise along the second direction and adjacent to the fourth active region, the backside via extends lengthwise along the first direction and connects to a sixth source/drain region in the fifth active region. In some embodiments, the semiconductor structure further includes a backside metal line disposed below the fourth active region and connected to the backside via. In some embodiments, the first backside butted contact extends into the second gate structure, and the second backside butted contact extends into the third gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an active region comprising a semiconductor fin base, a stack of nanostructures over the semiconductor fin base, and an epitaxial feature over the semiconductor fin base and connected to at least one of the nanostructures, the active region extending lengthwise in a first direction;
a gate structure wrapping around each of the nanostructures, the gate structure extending lengthwise in a second direction perpendicular to the first direction; and
a backside butted contact disposed directly under and electrically connected to the epitaxial feature and the gate structure,
wherein a portion of the backside butted contact extends into the gate structure and the epitaxial feature.

2. The semiconductor structure of claim 1, wherein a top surface of the backside butted contact is above a top surface of the semiconductor fin base and below a bottom surface of a topmost nanostructure,
wherein the top surface of the semiconductor fin base interfaces with the gate structure.

3. The semiconductor structure of claim 1, further comprising a silicide layer disposed between the epitaxial feature and the backside butted contact.

4. The semiconductor structure of claim 3, wherein the silicide layer is further disposed between the gate structure and the backside butted contact.

5. The semiconductor structure of claim 1, wherein the epitaxial feature is disposed on a first side of the stack of nanostructures, and
wherein the semiconductor structure further comprises an isolation structure connected to the stack of nanostructures and disposed on a second side of the stack of nanostructures, the second side being opposite to the first side.

6. The semiconductor structure of claim 1, wherein the gate structure is a first gate structure, and the stack of nanostructures is a first stack of first nanostructures,
wherein the active region further comprises a second stack of second nanostructures over the semiconductor fin base and connected to the epitaxial feature,
wherein the semiconductor structure further comprises a second gate structure wrapping around each of the second nanostructures in forming a pull-up transistor of a memory cell.

7. A semiconductor structure, comprising:
a static random-access memory (SRAM) cell, comprising:
a first active region and a first portion of a second active region extending lengthwise along a first direction,
a first metal gate stack intersecting the first active region in forming a first pull-up transistor of the SRAM cell, the first metal gate stack extending lengthwise along a second direction perpendicular to the first direction,
a second metal gate stack intersecting the first portion of the second active region in forming a second pull-up transistor of the SRAM cell,
a first contact feature disposed below and connected with a first source/drain region of the first pull-up transistor and the second metal gate stack, and
a second contact feature disposed below and connected with a second source/drain region of the second pull-up transistor and the first metal gate stack; and
an interconnect structure disposed over the SRAM cell,
wherein the interconnect structure comprises a metal line connected to a third source/drain region of the first pull-up transistor and a fourth source/drain region of the second pull-up transistor by vias and source/drain contacts under the vias,
wherein in a top view, the metal line has continuous sidewalls extending lengthwise along the first direction.

8. The semiconductor structure of claim 7, wherein the first contact feature extends into the first source/drain region of the first pull-up transistor and the second metal gate stack, and
wherein the second contact feature extends into the second source/drain region of the second pull-up transistor and the first metal gate stack.

9. The semiconductor structure of claim 7, wherein the metal line has a first width in the second direction, the vias each have a second width in the second direction,
wherein the first width is equal to or greater than two times of the second width.

10. The semiconductor structure of claim 7, wherein the SRAM cell is a first SRAM cell;
wherein the semiconductor structure further comprises a second SRAM cell being a mirror image of the first SRAM cell with respect to a first symmetry line in the second direction; and
wherein the second SRAM cell comprises:
a third active region and a second portion of the second active region extending lengthwise along the first direction, the first and second portions of the second active region being continuous,
a third metal gate stack intersecting the second portion of the second active region in forming a third pull-up transistor of the second SRAM cell,
a fourth metal gate stack intersecting the third active region in forming a fourth pull-up transistor of the second SRAM cell,
a third contact feature disposed below and connected with a fifth source/drain region of the third pull-up transistor and the fourth metal gate stack, and
a fourth contact feature disposed below and connected with a sixth source/drain region of the fourth pull-up transistor and the third metal gate stack.

11. The semiconductor structure of claim 10, wherein the continuous sidewalls of the metal line extend over the second SRAM cell, and
wherein the metal line is electrically connected to a seventh source/drain region of the fourth pull-up transistor.

12. The semiconductor structure of claim 10, wherein the first SRAM cell further comprises a first pull-down transistor formed from a fourth active region and the second metal gate stack,
wherein the second SRAM cell further comprises a second pull-down transistor formed from the fourth active region and the third metal gate stack,
wherein the first pull-down transistor and the second pull-down transistor share an eighth source/drain region,
wherein the semiconductor structure further comprises a backside interconnect structure below the first SRAM cell and the second SRAM cell,
wherein the semiconductor structure comprises a backside metal line disposed below the fourth active region and connected to the eighth source/drain region by a backside via.

13. The semiconductor structure of claim 12, further comprising a third SRAM cell and a fourth SRAM cell being a mirror image of the first SRAM cell and the second SRAM cell with respect to a second symmetry line in the first direction,
wherein the backside via extends along the second direction to below the third SRAM cell and the fourth SRAM cell.

14. A semiconductor structure, comprising:
a first gate structure, a second gate structure, a third gate structure, and a fourth gate structure extending lengthwise along a first direction;
a first active region intersecting the first gate structure in forming a first pull-up transistor;
a second active region intersecting the second gate structure and the third gate structure in forming a second pull-up transistor and a third pull-up transistor, respectively;
a third active region intersecting the fourth gate structure in forming a fourth pull-up transistor;
a first frontside butted contact disposed over and connected to the first gate structure and a second source/drain region of the second pull-up transistor;
a second frontside butted contact disposed over and connected to the fourth gate structure and a third source/drain region of the third pull-up transistor;
a first backside butted contact disposed below and connected to the second gate structure and a first source/drain region of the first pull-up transistor; and
a second backside butted contact disposed below and connected to the third gate structure and a fourth source/drain region of the fourth pull-up transistor,
wherein the first active region, the second active region, and the third active region extend lengthwise along a second direction perpendicular to the first direction, and
wherein the first active region and the third active region align.

15. The semiconductor structure of claim 14, further comprising a frontside metal line disposed over the first gate structure, the second gate structure, the third gate structure, and the fourth gate structure,
wherein the frontside metal line extends lengthwise along the second direction,
wherein in a top view, the frontside metal line has a straight sidewall on a first side and second sidewalls on a second side opposite to the first side,
wherein the straight sidewall extends over the first gate structure, the second gate structure, the third gate structure, and the fourth gate structure,
wherein the second sidewalls comprise recessed portions facing the first frontside butted contact and the second frontside butted contact.

16. The semiconductor structure of claim 15, wherein the frontside metal line is electrically connected to a fifth source/drain region of the first pull-up transistor, a sixth source/drain region of the second pull-up transistor, and a seventh source/drain region of the fourth pull-up transistor.

17. The semiconductor structure of claim 14, further comprising a fourth active region extending lengthwise along the second direction and adjacent to the second active region,
wherein the second gate structure intersects with the fourth active region in forming a pull-down transistor,
wherein the semiconductor structure further comprises a backside via below and connected to a fifth source/drain region of the pull-down transistor.

18. The semiconductor structure of claim 17, further comprising a fifth active region extending lengthwise along the second direction and adjacent to the fourth active region,
wherein the backside via extends lengthwise along the first direction and connects to a sixth source/drain region in the fifth active region.

19. The semiconductor structure of claim 17, further comprising a backside metal line disposed below the fourth active region and connected to the backside via.

20. The semiconductor structure of claim 14, wherein the first backside butted contact extends into the second gate structure, and the second backside butted contact extends into the third gate structure.
